(19) United States
(12) Patent Application Publication
(10) Pub. No.: US 2007/0235876 A1
(43) Pub. Date: Oct. 11, 2007

(54) Method of forming an atomic layer thin film out of the liquid phase

(76) Inventor: Michael Goldstein, Sunnyvale, CA (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/394,732

(22) Filed: Mar. 30, 2006

(51) Int. Cl. H01L 23/52

(52) U.S. Cl. 257/758

(57) ABSTRACT

A method of processing a substrate is described. A coupling agent and a metal ion solution are applied to the substrate. An activating solution is applied to activate metal ions of the metal ion solution to create a metal film out of the ions.

### BACKGROUND OF THE INVENTION

1). Field of the Invention

Embodiments of this invention relate generally to a method of processing a substrate, and more particularly to a method of forming a uniform, atomic layer thin film out of the liquid phase.

2). Discussion of Related Art

Electroplating has been used to form interconnect and other structures on semiconductor substrates. For many integrated circuit applications, electroplating is no longer a viable option because of the large voltage drops that occur across the wafer. Electroplating also fails to produce optimal uniformity across the wafer and its deposition rate is often difficult to control.

Other metal deposition techniques have been developed as alternatives to electroplating. One technique, known as electroless plating, involves depositing metal on substrates using chemical rather than electrical means. In order for this technique to work, the substrate must first be coated with an activation layer. Then, a chemical process is performed which allows for the subsequent formation of metal using the activation layer. As with electroplating, electroplating also fails to produce optimal uniformity across the wafer and its deposition rate is too difficult to control, especially for purposes of forming very thin layers.

### BRIEF DESCRIPTION OF THE DRAWINGS

Embodiments of the invention are described by way of examples with reference to the accompanying drawings wherein:

FIG. 1 is a flow chart illustrating a method of processing a substrate according to an embodiment of the invention;

FIG. 2 shows cross-sectional side views during the processing of the substrate;

FIG. 3 illustrates a molecule of a coupling agent that is used in the process of FIG. 2;

FIG. 4 is a cross-sectional side view illustrating how a film that is formed in the process of FIG. 2 can be used as a seed layer when plating a metal structure of a microelectronic circuit; and

FIG. 5 is a block diagram of a computer system in which the structure of FIG. 4 may reside.

### DETAILED DESCRIPTION OF THE INVENTION

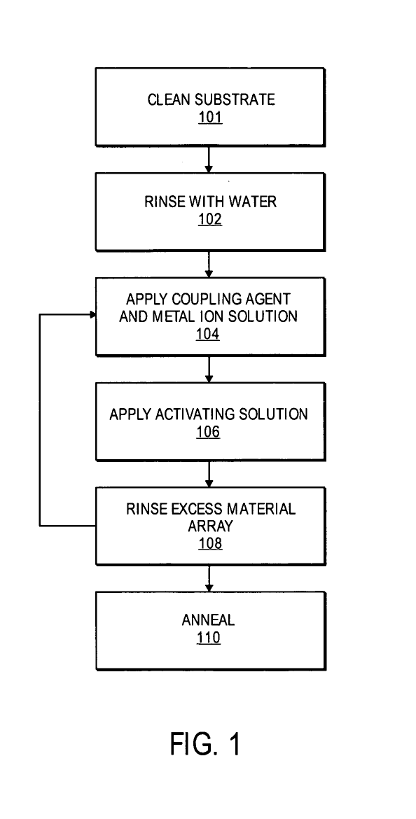

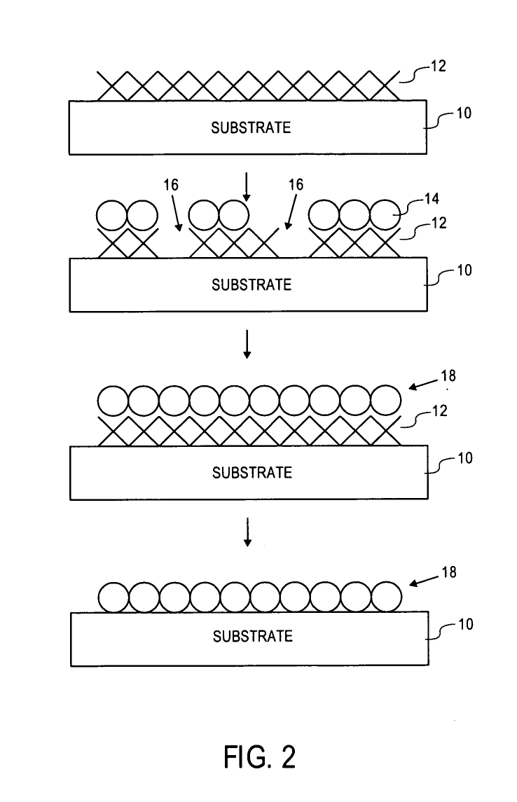

FIGS. 1 and 2 illustrate a method of processing a substrate, according to an embodiment of the invention. The method utilizes liquid phase materials to deposit a conformal, atomic layer of thin, uniform film. The film is deposited at a low temperature of between 50° C. and 70° C. and is annealed at a relatively low temperature of approximately 300° C.

At block 101, a substrate is cleaned. Cleaning of the substrate functionalizes its surface with OH— groups. A cleaner solution normally contains surfactants, phosphates or carbonates in an alkaline medium. Such a cleaner solutions makes a substrate more hydrophilic by functionalizing OH— groups.

At block 102, the substrate is rinsed with water. The water removes the remaining cleaner solution and thereby exposes the functionalized OH— groups.

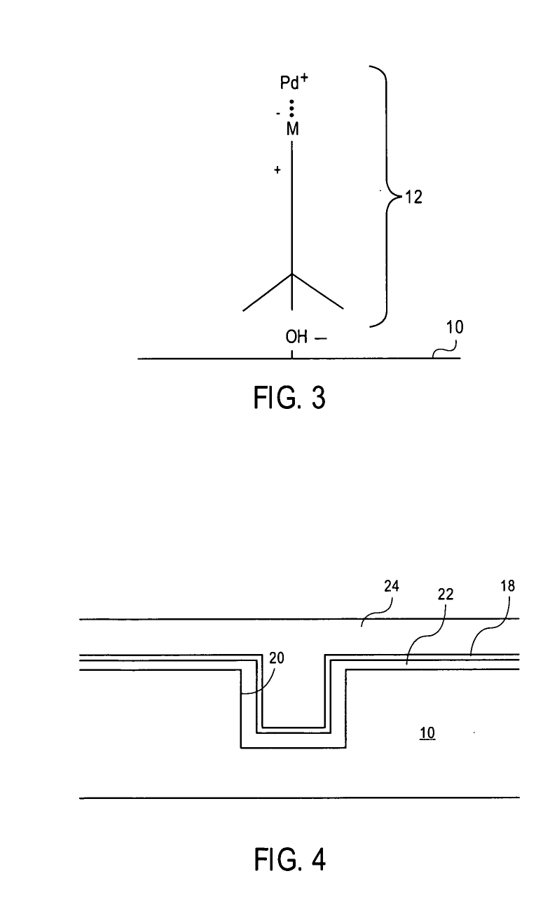

At block 104, a coupling agent and a metal ion solution are applied to the substrate. The substrate is indicated in FIG. 2 with reference 10 and the coupling agent and metal ion solution is indicated with reference 12. The coupling agent is preferably an amino silane. Amino silane such a imidizole silane or aminopropyl-trithoxy silane are good coupling agents for the platinum family of metals (the platinum family of metals include Pd, Ru and Pt) and amino silanes such as aminoethylamino-polyltrimethoxy silane derivatives are recommended for cobalt, nickel or copper immobilization. A molecule is formed between the coupling agent and an ion. An example of such a molecule is illustrated in FIG. 3 wherein the ion is Pd+.

At block 106, an activating solution is applied. The activating solution functionalizes the ions to leave a single layer of atoms 14 as a film on the remaining coupling agent 12. The activating solution contains reducing agents such as hypophosphorus acid or dimethylamine borane.

At block 108, excess material is rinsed away. Not all the ions of the coupling agent can normally be activated in one pass, so that pinholes 16 are usually left in the film formed by the metal atoms 14. The process in blocks 104, 106 and 108 is usually repeated one or more times, to leave a continuous film 18 without pinholes.

The process described with reference to blocks 104, 106 and 108 is a low temperature process. Both the coupling agent and the activating solution is applied in liquid phase at a temperature of between 50° C. and 70° C.

At block 110, the entire structure, including the film 18 and the coupling agent 12 is annealed. Annealing is carried out at a temperature below 320° C., typically at a temperature of approximately 300° C. The coupling agent 12 is made of an organic material that burns away at a relatively low temperature of approximately 300° C. Annealing thus removes the coupling agent 12 and leaves the film 18 directly on the substrate 10. Annealing also improves adhesion between the film 18 and the substrate 10.

As illustrated in FIG. 4, the process for forming the film 18 can be used for the formation of a metal seed layer in a plating operation. A trench 20 is formed in a silicon or interlayer dielectric layer of a substrate 10. A barrier layer 22 is then formed on the substrate 10, including on sidewalls and on a base of the trench 20. The barrier layer 22 is typically made of a metal such as tantalum or an alloy such as tantalum nitrate. The film 18 forms a seed layer that covers the barrier layer 22. The film 18 can then act as a seed layer for purposes of plating a metal layer 24 on the film 18. The film 18 and the metal layer are typically formed of the same metal, such as copper.

The metal layer 24 is subsequently planarized in a chemical-mechanical polishing operation, which also removes upper proportions of the film 18 and the barrier layer 22. A metal structure remains in the trench 20. The metal structure may be a plug, a via, or a metal line in the trench 20.

The substrate 10 and the metal structure formed in the trench 20 form a microelectronic structure that forms part of a microelectronic circuit. Such a microelectronic circuit may for example be a processor or memory of a computer.

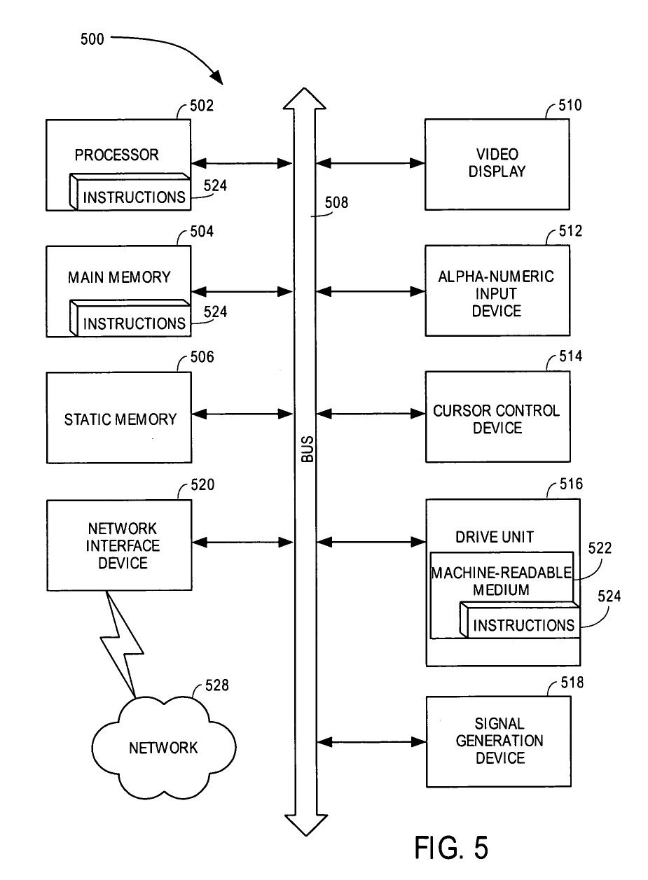

FIG. 5 shows a diagrammatic representation of a machine in the exemplary form of a computer system 500 that may include a microelectronic circuit having the microelectronic structure of FIG. 4. The machine may be a Personal Computer (PC), a tablet PC, a Set-Top Box (STB), a Personal Digital Assistant (PDA), a cellular telephone, a web appliance, a network router, a switch or bridge, or any machine capable of executing a set of instructions that specify actions to be taken by that machine.

Exemplary computer system 500 includes a processor 502, a main memory 504, and a static memory 506, which communicate with each other via a bus 508.

The computer system 500 may further include a video display 501. The computer system 500 also includes an alpha-numeric input device 512 (e.g., a keyboard), a cursor control device 514 (e.g., a mouse), a disk drive unit 516, a signal generation device 518 (e.g., a speaker), and a network interface device 520.

The described unit includes a machine-readable medium 522 on which is stored one or more sets of instructions 524 (e.g., software). The software may also reside, completely or at least partially, within the main memory 504 and/or within the processor 502 during execution thereof by the computer system 500, the main memory 504 and the processor 502 also constituting machine-readable media.

The software may further be transmitted or received via a network 528 via the network interface device 520.

Although the present invention has been described herein with reference to a number of illustrative embodiments, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses may also be apparent to those skilled in the art.

Furthermore, for ease of understanding, certain functional blocks may have been delineated as separate blocks; however, these separate delineated blocks should not necessarily be construed as being in the order in which they are discussed or otherwise represented herein. For example, some blocks may be able to be performed in an alternative ordering, simultaneously, etc.

What is claimed:

1. A method of processing a substrate, comprising:
applying a coupling agent and a metal ion solution to the substrate; and
applying an activating solution to activate metal ions of the metal ion solution to create a film out of the ions.

2. The method of claim 1, further comprising cleaning the substrate to functionalize OH— groups of the substrate, the coupling agent attaching to the OH-groups.

3. The method of claim 2, further comprising rinsing the substrate with water.

4. The method of claim 1, wherein the coupling agent is one of imidizole silane, aminopropyl-trithoxy silane or an aminoethylamino-polyltrimethoxy silane derivative.

5. The method of claim 1, wherein the coupling agent is one of imidizole silane or aminopropyl-trithoxy silane and the ions are ions from the platinum group, so that the metal film is made out of a metal from the platinum group.

6. The method of claim 1, wherein the coupling agent is an aminoethylamino-polyltrimethoxy silane derivative and the ions are cobalt, nickel or copper ions so that the metal film is a cobalt, nickel or copper film.

7. The method of claim 1, wherein the coupling agent is applied at a temperature of between 50° C. and 70° C.

8. The method of claim 1 wherein the activating solution is hypophosphorus acid or dimethylamine borane.

9. The method of claim 1, wherein the activating solution is applied at a temperature of between 50° C. and 70° C.

10. The method of claim 1, further comprising repeating:
applying a coupling agent and a metal ion solution to the substrate; and
applying an activating solution to activate the metal ions to create the film out of the ions.

11. The method of claim 1, further comprising annealing the metal film to remove the coupling agent.

12. The method of claim 11, wherein the metal film is annealed at a temperature of below 320° C.

13. The method of claim 1, further comprising:
forming a trench in the substrate;
forming a barrier layer on a base and on sidewalls of the trench, wherein the metal film is a metal seed layer formed on the barrier layers; and
plating a metal structure on the seed layer.

14. The method of claim 13, wherein the seed layer and the metal structure are of the same metal.

15. A method of processing a substrate, comprising:
(1) alternatingly:
(1.1) applying a coupling agent and a metal ion solution to the substrate; and
(1.2) applying an activating solution to activate the metal ions to create a metal film out of the ions; and
(2) annealing the metal film to remove the coupling agent.

16. The method of claim 15, wherein the coupling agent is one of the imidizole silane, aminopropyl-trithoxy silane or an aminoethylamino-polyltrimethoxy silane derivative.

17. The method of claim 15, wherein the activating solution is hypophosphorus acid or dimethylamine borane.

18. A microelectronic structure, comprising:
a substrate having a trench formed therein;
a barrier layer formed on a base and on side walls of the trench;
an atomic layer thickness seed layer formed on the barrier layer; and
a metal structure plated on the seed layer.

19. The microelectronic structure of claim 18, further comprising a processor, the metal structure forming part of the processor.

20. The microelectronic structure of claim 19, wherein the seed layer and the metal structure are of the same metal.
